(19) United States
(12) Patent Application Publication
(10) Pub. No.: US 2014/0071598 A1
(43) Pub. Date: Mar. 13, 2014

(54) CUP HOLDER ACCESSORY MOUNT

(71) Applicants: Robert Carreon, San Gabriel, CA (US); Dave Carreon, San Gabriel, CA (US); Matthew Carreon, San Gabriel, CA (US)

(72) Inventors: Robert Carreon, San Gabriel, CA (US); Dave Carreon, San Gabriel, CA (US); Matthew Carreon, San Gabriel, CA (US)

(21) Appl. No.: 13/610,485

(22) Filed: Sep. 11, 2012

(51) Int. Cl. F16M 13/02; H05K 7/00; F16M 11/00

(52) U.S. Cl. 361/679.01; 248/127; 248/121

(57) ABSTRACT

A cup holder accessory mount. The cup holder accessory mount includes a device body. The cup holder accessory mount further includes a mounting surface located at a first end of the device body. The mounting surface is non-porous, The mounting surface is configured to support a suction device of a suction-mounted accessory. The cup holder accessory mount further includes a device base located at a second end of the device body. The device base is configured to fit in a cup holder.

### BACKGROUND OF THE INVENTION

1. Field of the Invention

Embodiments of the invention described herein pertain to the field of vehicle accessories. More particularly, but not by way of limitation, one or more embodiments of the invention enable a cup holder accessory mount.

2. Description of the Related Art

Suction cups are a known method for attaching an object to a non-porous surface, such as glass. Other non-porous surfaces are also capable of coupling with a suction cup. In addition to glass, non-porous surfaces may be manufactured from plastics, such as acrylic, PVC, and other plastics.

Suction cup devices are often selected as a mounting mechanism for accessories in a vehicle. The accessories may include organizers, air fresheners, decorative devices, other non-electronic devices, and electronics devices such as global positioning system (GPS) enabled devices, cell phones, smart phones, other mobile devices, MP3 players, and other electronic devices.

A suction device, such as a suction cup, uses a vacuum space created when air is expelled by external pressure. In a vehicle, a non-porous surface must be available to mount a suction-mounted device. For example, the windshield of a vehicle is often selected as a non-porous surface. However, mounting a suction-mounted device on the windshield potentially occludes the visual field of the operator of the vehicle, thereby reducing safety. Another solution is to use a strong adhesive to mount a non-porous surface, such as a disc, to an interior surface of the vehicle. This may be considered a permanent mounting as the disc is not detachable unless permanently removed, often resulting in adhesive residue and potentially damaging the interior surface of the vehicle.

When the suction-mounted device is an electronic device, the device may include one or more cables, such as power cables, audio cables, A/V cables, data cables, and other cables. These cables may be configured to couple with a vehicle system, such as a power system, an audio system, a data system, or any other system. Depending on where the suction-mounted device is located, the cable may be poorly organized, requiring an additional solution to organize the cable.

To overcome the problems and limitations described above there is a need for a cup holder accessory mount.

### BRIEF SUMMARY OF THE INVENTION

A cup holder accessory mount device with a mounting surface configured to couple with a suction device provides a universal method to secure a suction mount of a device in a cup holder. The device may include electronic devices, such as GPS-devices, mobile devices, music players, PDAs, smart phones, iPods®, iPads®, and any other electronic devices. The mounting surface may also couple with non-electronic suction-mounted devices.

One or more embodiments of the cup holder accessory mount described herein are directed to a cup holder accessory mount including a device body. The device body may have a cylindrical shape. In one or more embodiments, the cylindrical shape is a tapered cylindrical shape, where a diameter of the first end of the device body is greater than a diameter of the second end of the device body.

In one or more embodiments, the device body has a weight of at least about 16 ounces.

The cup holder accessory mount further includes a mounting surface located at a first end of the device body. The mounting surface is non-porous. The mounting surface is configured to support a suction device of a suction-mounted accessory.

The cup holder accessory mount further includes a device base located at a second end of the device body. The device base is configured to fit in a cup holder. In one or more embodiments, the device base is configured to fit in a cup holder disposed in a vehicle. The device base may be weighted.

In one or more embodiments, the cup holder accessory mount of claim further includes a hollow interior configured to receive at least one cord. The device body may further include at least one cord passage configured to allow at least one cord to pass from the hollow interior to an exterior of the device body. The hollow interior may be configured to contain at least a middle section of the at least one cord, where the at least one cord passage is configured to allow a first end and a second end of the at least one cord to extend from the device body.

In one or more embodiments, the cup holder accessory mount further includes at least one high friction surface coupled with an exterior surface of said device body.

In one or more embodiments, the cup holder accessory mount further includes a hook-and-loop fastener coupled with at least one exterior surface of the device body.

In one or more embodiments, the mounting surface is disposed on a suction mounting module, where the suction mounting module is detachably coupled with the device body.

The cup holder accessory mount may further including an accessory docking module configured to secure an electronic device, where the accessory docking module is detachably coupled with the device body. The accessory docking module may further include at least one docking connector configured to communicate via electronic signals with the electronic device. The electronic device may be a mobile device. In one or more embodiments, the accessory docking module and the suction mounting module are interchangeable.

One or more embodiments of the cup holder accessory mount described herein are directed to a cup holder accessory mount including a device body including a cylindrical shape. The cylindrical shape may be a tapered cylindrical shape.

The device body may further include a hollow interior configured to receive at least one cord. In one or more embodiments, the hollow interior is configured to contain at least a middle section of the at least one cord, and where the at least one cord passage is configured to allow a first end and a second end of the at least one cord to extend from the device body.

The cup holder accessory mount further includes a suction mounting module including a mounting surface, where the suction mounting module is configured to detachably couple with a first end of the device body. The mounting surface may be non-porous, and may be configured to support a suction device of a suction-mounted accessory.

The cup holder accessory mount further includes a device base located at a second end of the device body, where the device base is configured to fit in a cup holder of a vehicle.

In one or more embodiments, the cup holder accessory mount further includes an accessory docking module configured to secure an electronic device, where the accessory docking module is configured to detachably couple with the first end of the device body.

The accessory docking module may further include at least one docking connector configured to communicate via electronic signals with the electronic device. In one or more embodiments, the accessory docking module and the suction mounting module are interchangeable.

### BRIEF DESCRIPTION OF THE DRAWINGS

The above and other aspects, features and advantages of the invention will be more apparent from the following more particular description thereof, presented in conjunction with the following drawings wherein:

FIG. 1 illustrates an exemplary cup holder accessory mount in accordance with one or more embodiments of the cup holder accessory mount described herein.

FIG. 2 illustrates a cross section of an exemplary cup holder accessory mount in accordance with one or more embodiments of the cup holder accessory mount described herein.

FIG. 3 illustrates a rear view of an exemplary cup holder accessory mount in accordance with one or more embodiments of the cup holder accessory mount described herein.

FIG. 4 illustrates a bottom view of an exemplary suction mounting module in accordance with one or more embodiments of the cup holder accessory mount described herein.

FIG. 5 illustrates a bottom view of an exemplary accessory docking module in accordance with one or more embodiments of the cup holder accessory mount described herein.

FIG. 6 illustrates an exemplary accessory docking module in accordance with one or more embodiments of the cup holder accessory mount described herein.

FIG. 7 illustrates an exemplary accessory docking module in accordance with one or more embodiments of the cup holder accessory mount described herein.

FIG. 8 illustrates an exploded view of an exemplary cup holder accessory mount and accessory docking module in accordance with one or more embodiments of the cup holder accessory mount described herein.

### DETAILED DESCRIPTION

A CUP HOLDER ACCESSORY MOUNT will now be described. In the following exemplary description numerous specific details are set forth in order to provide a more thorough understanding of embodiments of the invention. It will be apparent, however, to an artisan of ordinary skill that the present invention may be practiced without incorporating all aspects of the specific details described herein. Furthermore, although steps or processes are set forth in an exemplary order to provide an understanding of one or more systems and methods, the exemplary order is not meant to be limiting. One of ordinary skill in the art would recognize that the steps or processes may be performed in a different order, and that one or more steps or processes may be performed simultaneously or in multiple process flows without departing from the spirit or the scope of the invention. In other instances, specific features, quantities, or measurements well known to those of ordinary skill in the art have not been described in detail so as not to obscure the invention. Readers should note that although examples of the invention are set forth herein, the claims, and the full scope of any equivalents, are what define the metes and bounds of the invention.

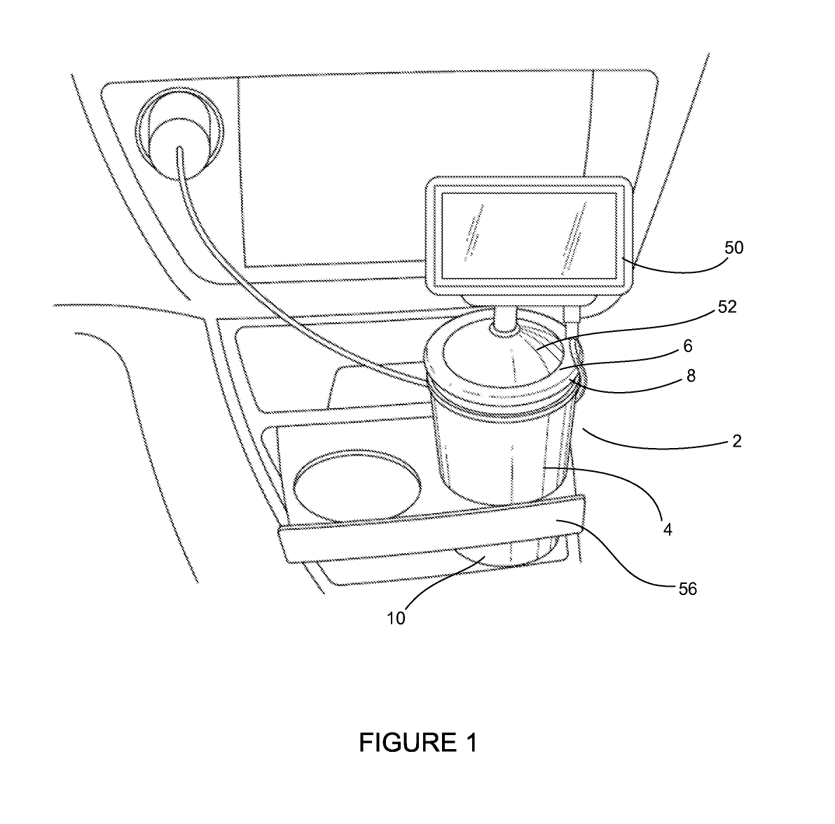

FIG. 1 illustrates an exemplary cup holder accessory mount in accordance with one or more embodiments of the cup holder accessory mount described herein. Device body 4 of cup holder accessory mount 2 includes mounting surface 6. Mounting surface 6 is a non-porous surface configured to support suction device 52 of suction-mounted accessory 50. Suction-mounted accessory may include any electronic or non-electronic accessory with a suction mount, including but not limited to organizers, air fresheners, decorative devices, global positioning system (GPS) enabled devices, cell phones, smart phones, other mobile devices, MP3 players, and any other non-electronic or electronic device.

In one or more embodiments, suction device 52 is any device that uses a partial vacuum to create negative fluid pressure, such as a suction cup or any other suitable device. As used herein, the term “non-porous surface” refers to any substantially non-porous surface suitable for use with a suction device.

Device body 4 further includes device base 10. Device base 10 is configured to fit into a cup holder, such as cup holder 56. As used herein, the term “cup holder” refers to any device configured to receive at least a portion of a cup or bottle-shaped receptacle. For example, device base 10 may be configured to fit in a cup holder of a vehicle, exercise equipment, indoor and outdoor seating, or any other location a cup holder may be disposed. In one or more embodiments, mounting surface 6 is disposed on a first end of device body 4, and device base 10 is disposed on a second end of device body 4.

In one or more embodiments, device body 4 has a cylindrical shape. The cylindrical shape may be a tapered cylindrical shape such that a diameter of a first end of device body 4 with mounting surface 6 has a greater diameter than the second end of device body 4 with device base 10.

Device body 4 may be sized for universal fit such that the typical cup holder is expected to accommodate device base 10. Device body 4 may be also sized for universal fit such that the typical suction-mounted accessory is expected to fit on mounting surface 6.

In one or more embodiments, device base 10 has a diameter of between about 2 inches to about 3 inches. In one or more preferred embodiments, device base 10 has a diameter of between about 2.25 inches to about 2.75 inches.

In one or more embodiments, mounting surface 6 has a diameter of between about 3 inches to about 4 inches. In one or more preferred embodiments, mounting surface 6 has a diameter of between about 3.25 inches to about 3.75 inches.

Device body 4 may be manufactured from metal, wood, plastic (including but not limited to acrylic, polyethylene terephthalate, polyethylene, high-density polyethylene, polyvinyl chloride, low-density polyethylene, polypropylene, polystyrene, high impact polystyrene, polyamides, acrylonitrile butadiene styrene, polycarbonate, polycarbonate/acrylonitrile butadiene styrene, polyurethanes, and any other plastic), and/or any other suitable material.

At least a portion of device body 4 may be weighted. For example, device body 4 may be weighted with an additional weight. The additional weight may be placed within device body 4, outside device body 4, or imbedded inside device body 4. Alternatively, device body 4 may be manufactured with enough material to achieve a desired weight. In one or more embodiments, device base 10 is weighted. In one or more embodiments, device body has a weight of at least about 12 ounces. Device body may have a weight of at least about 16 ounces.

Mounting surface 6 may be disposed on a suction mounting module 8. Suction mounting module 8 may be a detachably coupled with device body 4. For purposes of description, suction mounting module 8 and any interchangeable module may be considered a component of device body 4 when coupled with device body 4. In one or more embodiments, suction mounting module 8 may be interchangeable with one or more accessory docking modules, such as the exemplary accessory docking modules shown in FIGS. 5-8.

In one or more embodiments, suction mounting module 8 may couple with device body 4 by at least one threaded portion of suction mounting module 8 and device body 4. Suction mounting module 8 may sized to fit tightly with device body 4. Any coupling device may be used to detachably couple suction mounting module 8 with device body 4, including a latch, screw, buckle, snap, lever or any other coupling and/or decoupling device.

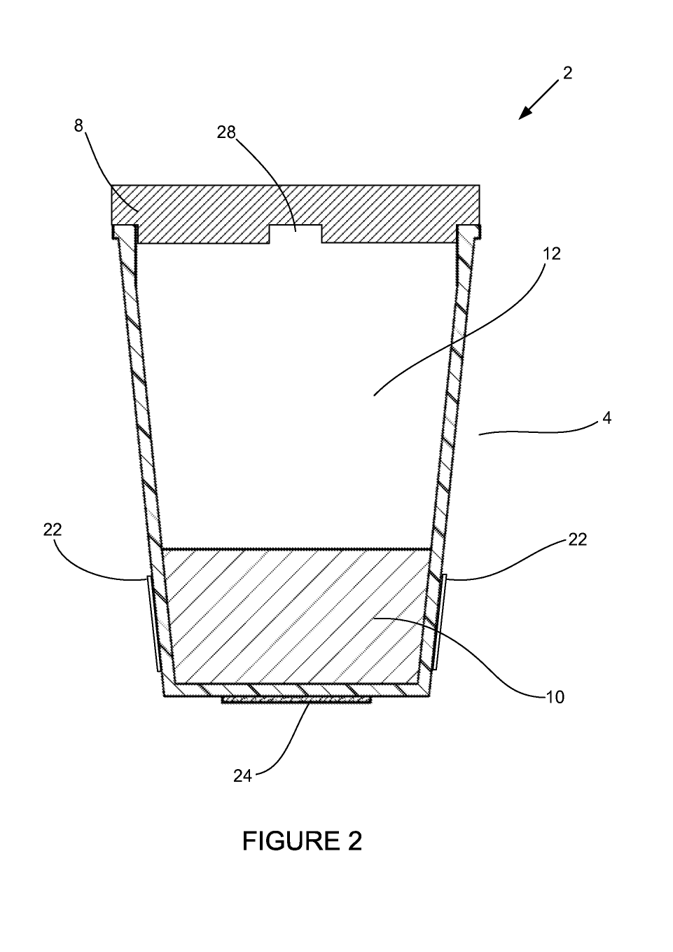

FIG. 2 illustrates a cross section of an exemplary cup holder accessory mount in accordance with one or more embodiments of the cup holder accessory mount described herein.

Device body 4 of cup holder accessory mount 2 may include hollow interior 12. Hollow interior 12 is configured to receive at least one cord, such as a cord of an electronic device. In one or more embodiments, at least a portion of a cord of an electronic device is placed in hollow interior 12 by detaching suction mounting module 8.

Device body 4 may further include at least one cord passage 28. Cord passage 28 is configured to allow at least one cord to pass from hollow interior 12 to an exterior of device body 4. In one or more embodiments, at least one end of a cord contained within hollow interior 12 passes through cord passage 28 to an exterior of device body 4. Cord passage 28 may be disposed on device body 4. In one or more embodiments, cord passage 28 is disposed on suction mounting module 8 or any interchangeable accessory docking module, such as the exemplary accessory docking modules shown in FIGS. 5-8. Alternatively, cord passage 28 may be disposed on a portion of device body 4 adjacent to suction mounting module 8 or any interchangeable accessory docking module. Cord passage 28 may be disposed on any other portion of device body 4.

In one or more embodiments, device base 10 is weighted. Device base 10 may be weighted with an additional weight. The additional weight may be placed within device body 4, outside device body 4, or imbedded inside device body 4. Alternatively, device body 4 may be manufactured with sufficient material at device base 10 to achieve a desired weight.

Cup holder accessory mount 2 may further include at least one high friction surface 22 coupled with an exterior surface of device body 4. In one or more embodiments, at least one high friction surface 22 is coupled with an exterior surface of device base 10. High friction surface 22 may be coupled using adhesive, glue, tape, staples, screws, or any other suitable method. In one or more embodiments, high friction surface 22 is manufactured directly into a surface of device body 4. In one or more embodiments, high friction surface 22 includes a rubberized surface, such as a rubberized coating, tape, sleeve, strip, or any other rubberized surface. As used herein, the term “high friction surface” refers to any surface with a friction greater than the surface of device body 4 to which the high friction surface is coupled.

Cup holder accessory mount 2 may further include at least one hook-and-loop fastener 24 coupled with an exterior surface of device body 4. In one or more embodiments, at least one one hook-and-loop fastener 24 is coupled with an exterior surface of device base 10. Hook-and-loop fastener 24 may be provided uncoupled with device body 4 with instructions to couple one surface of hook-and-loop fastener 24 with device body 4 and a second surface of one hook-and-loop fastener 24 with a surface of a cup holder, allowing device body 4 to detachably couple with the cup holder via hook-and-loop fastener 24. Hook-and-loop fastener 24 may be coupled to device body 4 using adhesive, glue, tape, or any other suitable method.

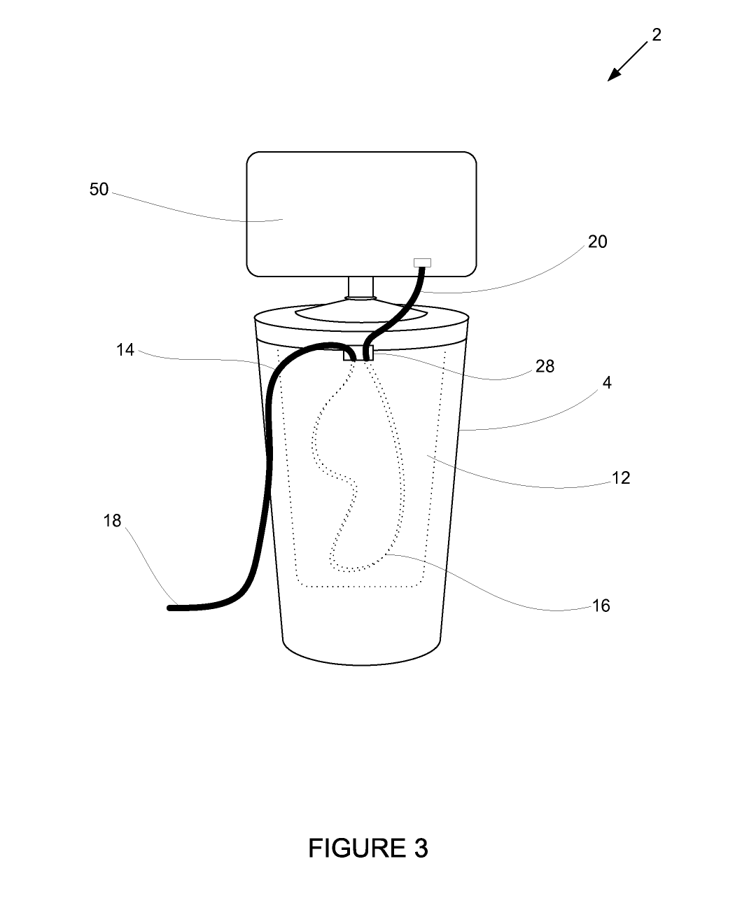

FIG. 3 illustrates a rear view of an exemplary cup holder accessory mount in accordance with one or more embodiments of the cup holder accessory mount described herein. In one or more embodiments, hollow interior 12 of cup holder accessory mount 2 is configured to contain at least a middle section 16 of at least one cord 14.

Cord passage 28 is configured to allow a first end 18 and a second end 20 of cord 14 to extend from device body 14. Hollow interior 12 may be configured to fit any amount of cord 14 to organize cord 14 within device body 4. Cord passage 28 and hollow interior 12 may be configured to accommodate more than one cord.

In one or more embodiments, suction mounting module 8 or any interchangeable accessory docking module, such as the exemplary accessory docking modules shown in FIGS. 5-8, is detachably coupled to facilitate placement of cord 14 in hollow interior 12.

In one or more embodiments, second end 20 of cord 14 is configured to couple with accessory 50. First end 18 of cord 14 may be configured to couple with a vehicle system, such as a power system, an audio system, a data system, or any other system. For example, the vehicle system may be a power source, such as a 12 volt DC power source typically available in a vehicle.

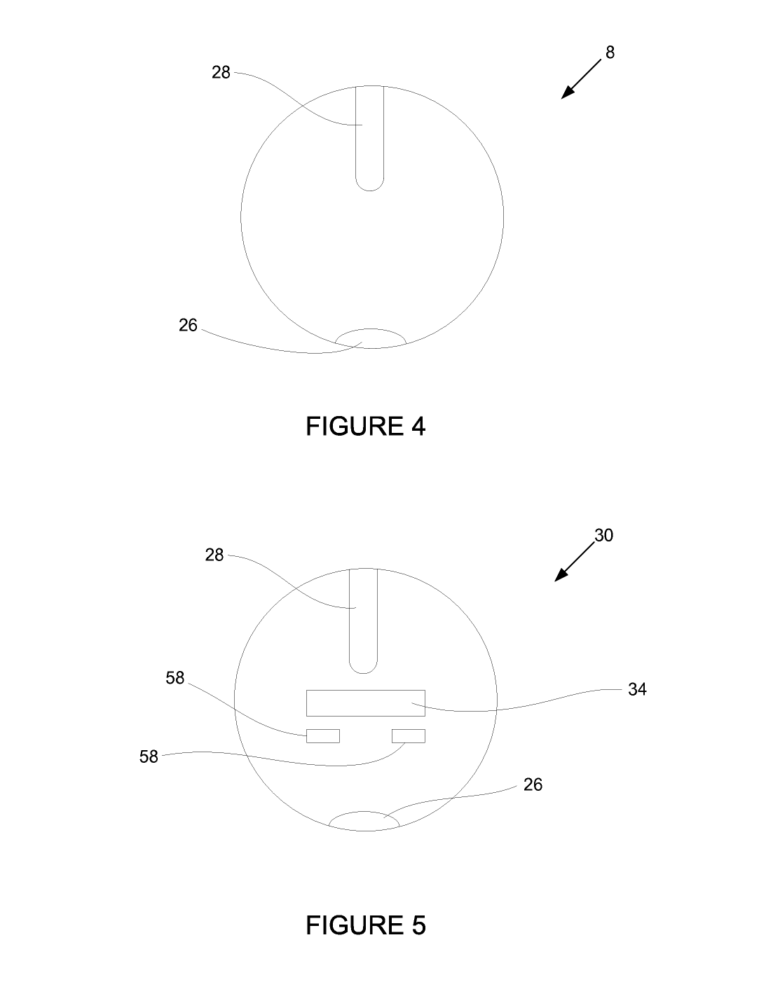

FIG. 4 illustrates a bottom view of an exemplary suction mounting module in accordance with one or more embodiments of the cup holder accessory mount described herein.

Suction mounting module 8 includes cord passage 28. Cord passage 28 is configured to allow at least one cord to pass from an interior of the device body to an exterior of the device body. Cord passage 28 may be configured to allow a first end and/or a second end of at least one cord to extend from a cup holder accessory mount when suction mounting module 8 is coupled with a device body of the cup holder accessory mount. Alternatively, in one or more embodiments, a cord passage is disposed on a portion of device body 4 rather than in accessory docking module 30.

In one or more embodiments, suction mounting module 8 includes leverage slot 26. Leverage slot 26 is configured to facilitate the removal of suction mounting module 8 from the device body. Leverage slot 26 may be operated using a coin, a key, a flathead screwdriver, or any other device suitable for removing suction mounting module 8 and/or any accessory docking module using leverage.

FIG. 5 illustrates a bottom view of an exemplary accessory docking module in accordance with one or more embodiments of the cup holder accessory mount described herein.

Accessory docking module 30 includes cord passage 28. Cord passage 28 is configured to allow at least one cord to pass. In one or more embodiments, cord passage 28 is configured to allow an end of at least one cord to extend from a cup holder accessory mount when accessory docking module 30 is coupled with a device body of the cup holder accessory mount. In one or more embodiments, cord passage 28 is configured to accommodate a first end a cord configured to couple with a vehicle system, such as a power system, an audio system, a data system, or any other system. Alternatively, in one or more embodiments, a cord passage is disposed on a portion of device body 4 rather than in accessory docking module 30.

In one or more embodiments, accessory docking module 30 further includes accessory passage 34. Accessory passage 34 is configured to allow an end of at least one cord to pass through accessory docking module 30 from the hollow interior of the device body. In one or more embodiments, accessory passage 34 is configured to accommodate a second end of a cord configured to couple with an electronic accessory, such as a global positioning system (GPS) enabled device, cell phone, smart phone, MP3 player, and any other electronic device.

In one or more embodiments, accessory docking module 30 further includes one or more auxiliary passage 58. Auxiliary passages 58 may be positioned based on an expected electronic accessory. For example, auxiliary passage 58 may be positioned based on the location of a speaker, microphone, cord, port, or any other component of an expected electronic accessory. Auxiliary passage 58 may be a partially open passage, such as a passage covered with mesh, fabric, or any other covering.

In one or more embodiments, accessory docking module 30 includes leverage slot 26. Leverage slot 26 is configured to facilitate the removal of accessory docking module 30 from device body 4.

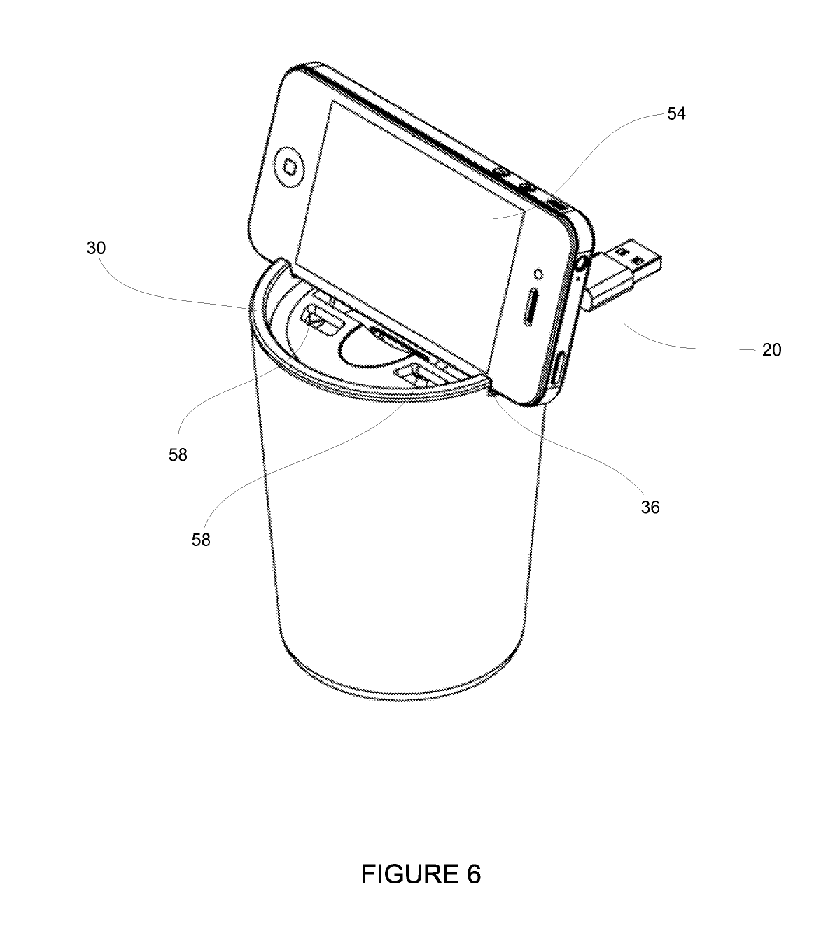

FIG. 6 illustrates an exemplary accessory docking module in accordance with one or more embodiments of the cup holder accessory mount described herein.

Accessory docking module 30 includes accessory stand 36. Accessory stand 36 is configured to receive accessory 54. In one or more embodiments, accessory stand 36 is configured to support accessory 54 in a usable position. Accessory 54 may include electronic devices such as global positioning system (GPS) enabled devices, cell phones, smart phones, other mobile devices, MP3 players, and other electronic devices.

In one or more embodiments, accessory docking module 30 further includes one or more auxiliary passage 58. Auxiliary passages 58 may be positioned based on an expected electronic accessory. For example, auxiliary passage 58 may be positioned based on the location of a speaker, microphone, cord, port, or any other component of an expected electronic accessory. Auxiliary passage 58 may be a partially open passage, such as a passage covered with mesh, fabric, or any other covering.

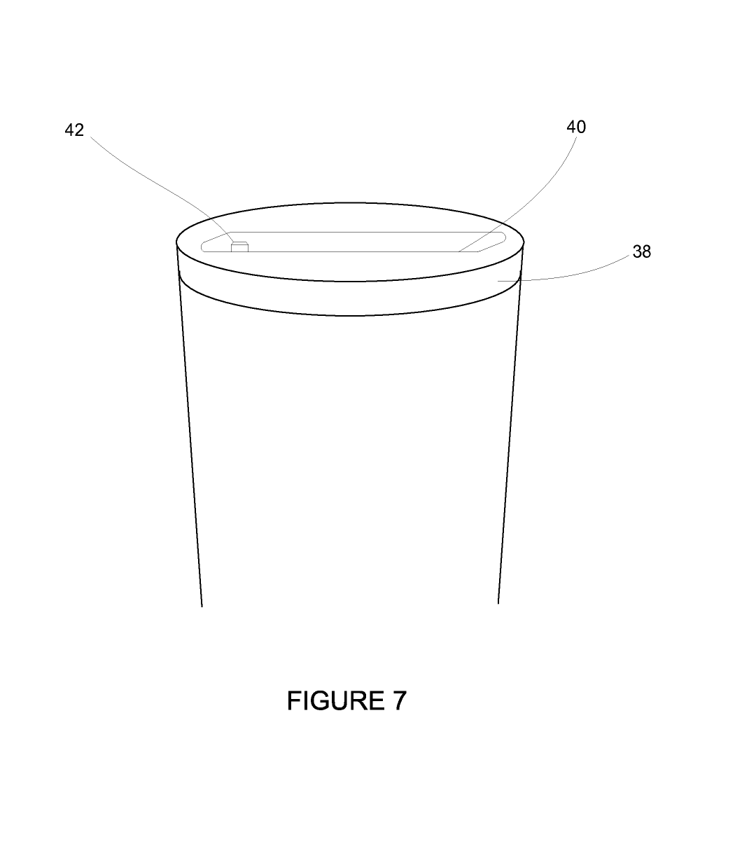

FIG. 7 illustrates an exemplary accessory docking module in accordance with one or more embodiments of the cup holder accessory mount described herein.

Accessory docking module 38 includes accessory stand 40. Accessory stand 40 is configured to receive an electronic accessory, such as a global positioning system (GPS) enabled device, a cell phone, a smart phone, another mobile device, an MP3 players and other electronic device. In one or more embodiments, accessory stand 40 is configured to support an electronic accessory in a usable position. In one or more embodiments, accessory stand 40 may be configured to accept the specific electronic device in both a landscape position and a portrait position. Accessory docking module 38 may be customized to a specific electronic device, including a specific brand or a specific model.

Accessory docking module 38 may further include at least one docking connector 42. Docking connector 42 is configured to couple with the electronic accessory to provide a power and/or data connection to the electronic accessory. In one or more embodiments, accessory docking module 38 is wired to accept a cable connector matching docking connector 42. Alternatively, accessory docking module 38 may include at least one cable configured to connect the electronic accessory to a vehicle power and/or data system, thereby substituting the cable. Alternatively, accessory docking module 38 may include at least one power source configured to at as a substitute power source for the electronic accessory.

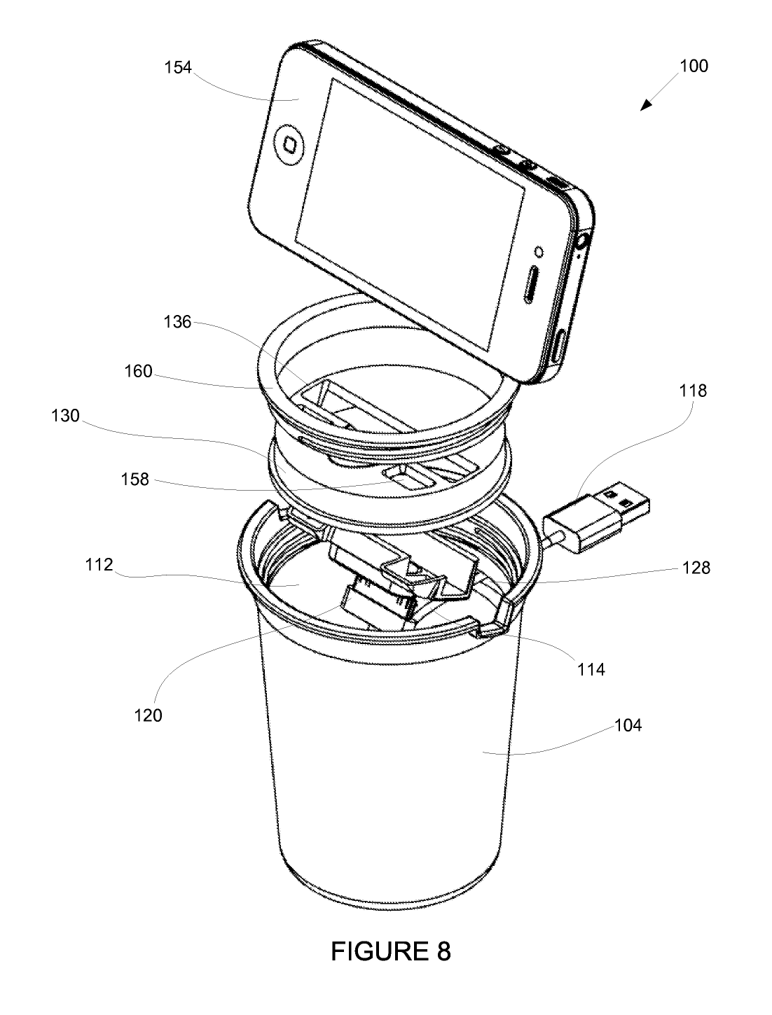

FIG. 8 illustrates an exploded view of an exemplary cup holder accessory mount and accessory docking module in accordance with one or more embodiments of the cup holder accessory mount described herein. Cup holder accessory mount 100 is configured to hold accessory 154. In one or more embodiments, cup holder accessory mount 100 is configured to support accessory 154 in a usable position. Accessory 154 may include electronic devices such as global positioning system (GPS) enabled devices, cell phones, smart phones, other mobile devices, MP3 players, and other electronic devices.

Device body 104 of cup holder accessory mount 100 is configured to fit into a cup holder. For example, device body 104 may be configured to fit in a cup holder of a vehicle, exercise equipment, indoor and outdoor seating, or any other location a cup holder may be disposed.

Cup holder accessory mount 100 includes accessory docking module 130. Accessory docking module 130 may be a detachably coupled with device body 104. Accessory docking module 130 includes accessory stand 136. Accessory stand 136 is configured to receive accessory 154. In one or more embodiments, accessory stand 136 is configured to support accessory 154 in a usable position. Accessory stand 136 may be configured to receive accessory 154 in both landscape and portrait orientations. Accessory 154 may include electronic devices such as global positioning system (GPS) enabled devices, cell phones, smart phones, other mobile devices, MP3 players, and other electronic devices.

Accessory docking module 136 may be customized to a specific electronic device, including a specific brand or a specific model. In one or more embodiments, multiple accessory docking modules, such as accessory docking modules for different accessories, are interchangeable. Master module coupler 160 may be used to couple different accessory docking modules with device body 104. In one or more embodiments, accessory docking module 136 is interchangeable with a suction mounting module, such as the suction mounting modules shown in FIGS. 1-4.

In one or more embodiments, accessory docking module 136 may couple with device body 104 by at least one threaded portion of accessory docking module 136 and device body 104. Alternatively, accessory docking module 136 may sized to fit tightly with device body 104. Any coupling device may be used to detachably couple accessory docking module 136 with device body 104, including a latch, screw, buckle, snap, lever or any other coupling and/or decoupling device.

Hollow interior 112 of cup holder accessory mount 110 is configured to contain at least a section of at least one cord 114. Device body 104 includes cord passage 128. Cord passage 128 is configured to allow at least one cord to pass. In one or more embodiments, cord passage 128 is configured to allow an end of at least one cord 114 to extend from cup holder accessory mount 100. In one or more embodiments, cord passage 28 is configured to accommodate a first end 118 of cord 114 configured to couple with a vehicle system, such as a power system, an audio system, a data system, or any other system.

In one or more embodiments, a second end 120 of cord 114 is configured to attach to accessory 154. Accessory docking module 136 may be configured to facilitate the connection of second end 120 of cord 114 with accessory 154.

In one or more embodiments, accessory docking module 130 further includes one or more auxiliary passage 158. Auxiliary passages 158 may be positioned based on an expected electronic accessory. For example, auxiliary passage 158 may be positioned based on the location of a speaker, microphone, cord, port, or any other component of an expected electronic accessory. Auxiliary passage 158 may be a partially open passage, such as a passage covered with mesh, fabric, or any other covering.

While the invention herein disclosed has been described by means of specific embodiments and applications thereof, numerous modifications and variations could be made thereto by those skilled in the art without departing from the scope of the invention set forth in the claims.

What is claimed is:

1. A cup holder accessory mount comprising:
a device body;
a mounting surface a first end of said device body, wherein said mounting surface is non-porous, whereby said mounting surface is configured to support a suction device of a suction-mounted accessory; and
a device base located at a second end of said device body, wherein said device base is configured to fit in a cup holder.

2. The cup holder accessory mount of claim 1, wherein said device body has a weight of at least about 16 ounces.

3. The cup holder accessory mount of claim 1, wherein said device base is weighted.

4. The cup holder accessory mount of claim 1, wherein said device body comprises a cylindrical shape.

5. The cup holder accessory mount of claim 4, wherein said cylindrical shape is a tapered cylindrical shape, wherein a diameter of said first end of said device body is greater than a diameter of said second end of said device body.

6. The cup holder accessory mount of claim 1, wherein said device base is configured to fit in a cup holder disposed in a vehicle.

7. The cup holder accessory mount of claim 1, further comprising a hollow interior configured to receive at least one cord.

8. The cup holder accessory mount of claim 7, wherein said device body further comprises at least one cord passage configured to allow at least one cord to pass from said hollow interior to an exterior of said device body.

9. The cup holder accessory mount of claim 8, wherein said hollow interior is configured to contain at least a middle section of said at least one cord, and wherein said at least one cord passage is configured to allow a first end and a second end of said at least one cord to extend from said device body.

10. The cup holder accessory mount of claim 1, further comprising at least one high friction surface coupled with an exterior surface of said device body.

11. The cup holder accessory mount of claim 1, further comprising a hook-and-loop fastener coupled with at least one exterior surface of said device body.

12. The cup holder accessory mount of claim 1, wherein said mounting surface is disposed on a suction mounting module, wherein said suction mounting module is detachably coupled with said device body.

13. The cup holder accessory mount of claim 12, further comprising an accessory docking module configured to secure an electronic device, wherein said accessory docking module is detachably coupled with said device body, wherein said accessory docking module and said suction mounting module are interchangeable.

14. The cup holder accessory mount of claim 13, wherein said electronic device is a mobile device.

15. The cup holder accessory mount of claim 13, wherein said accessory docking module further comprises at least one docking connector configured to communicate via electronic signals with said electronic device.

16. A cup holder accessory mount comprising:
a device body comprising a cylindrical shape, wherein said device body further comprises a hollow interior configured to receive at least one cord;
a suction mounting module comprising a mounting surface, wherein said suction mounting module is configured to detachably couple with a first end of said device body, wherein said mounting surface is non-porous, whereby said mounting surface is configured to support a suction device of a suction-mounted accessory;
a device base located at a second end of said device body, wherein said device base is configured to fit in a cup holder of a vehicle.

17. The cup holder accessory mount of claim 16, wherein said cylindrical shape is a tapered cylindrical shape.

18. The cup holder accessory mount of claim 16, further comprising an accessory docking module configured to secure an electronic device, wherein said accessory docking module is configured to detachably couple with said first end of said device body, wherein said accessory docking module and said suction mounting module are interchangeable.

19. The cup holder accessory mount of claim 18, wherein said accessory docking module further comprises at least one docking connector configured to communicate via electronic signals with said electronic device.

20. The cup holder accessory mount of claim 16, wherein said hollow interior is configured to contain at least a middle section of said at least one cord, and wherein said at least one cord passage is configured to allow a first end and a second end of said at least one cord to extend from said device body.
